(19) United States
(12) Patent Application Publication
(10) Pub. No.: US 2026/0047318 A1
(43) Pub. Date: Feb. 12, 2026

(54) DISPLAY DEVICE

(71) Applicant: LG Display Co., Ltd., Seoul (KR)

(72) Inventors: Jongmoo Ha, Paju-si (KR); Soobin Lee, Paju-si (KR)

(73) Assignee: LG Display Co., Ltd., Seoul (KR)

(21) Appl. No.: 19/257,984

(22) Filed: Jul. 2, 2025

(30) Foreign Application Priority Data
Aug. 12, 2024 (KR) 10-2024-0107434

(51) Int. Cl. H10K 59/80; G06F 3/041; G06F 3/044; H10H 29/37; H10H 29/49; H10K 59/122; H10K 59/131; H10K 59/40; H10K 102/00

(52) U.S. Cl. CPC H10K 59/871; G06F 3/04164; G06F 3/0446; H10H 29/37; H10H 29/49; H10K 59/122; H10K 59/131; H10K 59/40; G06F 2203/04106; H10K 2102/311

(57) ABSTRACT

A display device includes a base substrate including a display area and a non-display area, a planarization layer disposed on the base substrate, a bank disposed on the planarization layer, a touch buffer layer disposed on a portion of the bank and the planarization layer, a touch sensor portion disposed on the touch buffer layer, and a protective layer covering the touch sensor portion on the touch buffer layer.

### CROSS-REFERENCE TO RELATED APPLICATION

This application claims priority from Korean Patent Application No. 10-2024-0107434, filed on Aug. 12, 2024, which is hereby incorporated by reference for all purposes as if fully set forth herein.

### BACKGROUND

### Field

Embodiments of the present disclosure relate to a display device.

### Description of Related Art

The advent of the information age leads to a fast advance in the field of displays which visually display electrical information signals, and steady research efforts to develop compact and lightweight, low-power displays while enhancing the performance of displays.

Representative display devices include liquid crystal displays (LCD), field emission displays (FED), electro-wetting displays (EWD), and organic light emitting displays (OLED).

Organic light emitting displays, as self-luminous, do not require a separate light source, unlike liquid crystal displays, and may be manufactured in a slim and lightweight form. Further, organic light emitting displays are not only advantageous in terms of power consumption due to low-voltage operation, but also have excellent color expression, response speed, viewing angle, and contrast ratio (CR), and are thus expected to be utilized in various fields.

### SUMMARY

Embodiments of the present disclosure may provide a display device capable of preventing or suppressing corrosion of a line used for evaluating product driving reliability because tetramethylammonium hydroxide (TMAH) does not remain on the surface of a bank positioned in a bending area.

Embodiments of the present disclosure may provide a display device in which it is easy to adjust the position of a neutral plane formed in the bending area by forming a concave curved pattern on the surface of the base substrate positioned in the bending area.

Embodiments of the present disclosure may provide a display device capable of preventing or suppressing cracks from occurring in a display panel during bending by forming a metal layer and an inorganic material layer not to be disposed in a bending area.

To achieve these and other objects and advantages of the present disclosure, as embodied and broadly described herein, a display device comprises a base substrate including a display area and a non-display area, a planarization layer disposed on the base substrate, a bank disposed on the planarization layer, a touch buffer layer disposed on a portion of the bank and the planarization layer, a touch sensor portion disposed on the touch buffer layer, and a protective layer covering the touch sensor portion on the touch buffer layer.

According to embodiments of the present disclosure, there may be provided a display device capable of preventing or suppressing corrosion of a line used for evaluating product driving reliability because tetramethylammonium hydroxide (TMAH) does not remain on the surface of a bank positioned in a bending area.

According to embodiments of the present disclosure, there may be provided a display device in which it is easy to adjust the position of a neutral plane formed in the bending area by forming a concave curved pattern on the surface of the base substrate positioned in the bending area.

According to embodiments of the present disclosure, there may be provided a display device capable of preventing or suppressing cracks from occurring in a display panel during bending by forming a metal layer and an inorganic material layer not to be disposed in a bending area.

According to embodiments of the present disclosure, a lightweight display device may be provided by removing the metal layer and the inorganic material layer disposed in the bending area.

### BRIEF DESCRIPTION OF DRAWINGS

The accompanying drawings, that are included to provide a further understanding of the disclosure and are incorporated in and constitute a part of the disclosure, illustrate example embodiments of the disclosure and together with the description serve to explain various principles of the disclosure. In the drawings:

FIG. 1 is a view illustrating a configuration of a display device according to example embodiments of the disclosure;

FIG. 2 is a view illustrating a display panel according to an example embodiment of the disclosure;

FIG. 3 is a plan view illustrating a display panel according to example embodiments of the disclosure;

FIG. 4 is a cross-sectional view taken along line A-A′ in FIG. 3;

FIG. 5 is a cross-sectional view taken along line B-B′ in FIG. 3;

FIG. 6 is a cross-sectional view taken along line C-C′ in FIG. 3;

FIGS. 7 to 9 are cross-sectional views illustrating a display panel according to another example embodiment of the disclosure;

FIG. 10 is a view illustrating a process sequence for manufacturing a display device according to an example embodiment of the disclosure; and

FIG. 11 is a view illustrating a process sequence for manufacturing a display device according to another example embodiment of the disclosure.

### DETAILED DESCRIPTION

Hereinafter, example embodiments of the disclosure are described in detail with reference to the accompanying drawings. In assigning reference numerals to components of each drawing, the same components may be assigned the same numerals even when they are shown on different drawings. When determined to make the subject matter of the disclosure unclear, the detailed of the known art or functions may be skipped. As used herein, where a component “includes,” “has,” or “is composed of” another component, the component may add other components unless the component “only” includes, has, or is composed of the other component. As used herein, the singular forms “a”, “an” and “the” are intended to include the plural forms as well, unless the context clearly indicates otherwise.

Such denotations as “first,” “second,” “A,” “B,” “(a),” and “(b),” may be used in describing the components of the disclosure. These denotations are provided merely to refer to a component separately from another, and the essence, order, or number of the components are not limited by the denotations.

In describing the positional relationship between components, where two or more components are described as “connected”, “coupled” or “linked”, the two or more components may be directly “connected”, “coupled” or “linked”“, or another component may intervene. Here, the other component may be included in one or more of the two or more components that are “connected”, “coupled” or “linked” to each other.

Where such terms as, e.g., “after”, “next to”, “after”, and “before”, are used to describe the temporal flow relationship related to components, operation methods, and fabricating methods, it may include a non-continuous relationship unless a more limiting term like “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various example embodiments of the disclosure are described in detail with reference to the accompanying drawings.

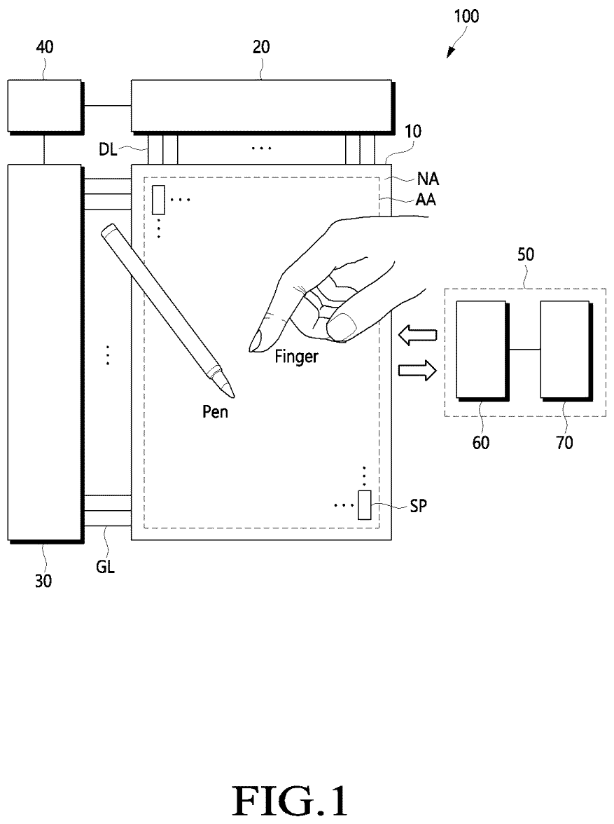

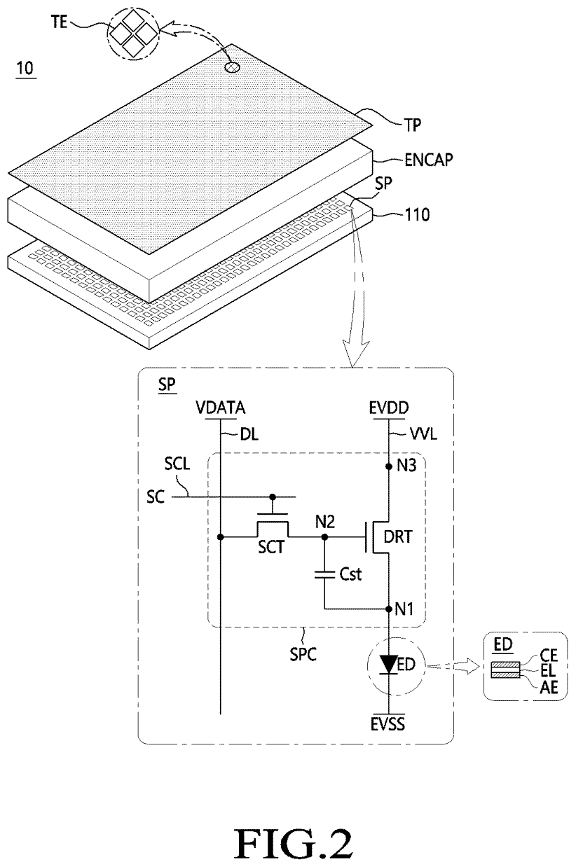

FIG. 1 is a view illustrating a configuration of a display device according to example embodiments of the disclosure. FIG. 2 is a view illustrating a display panel according to example embodiments of the disclosure.

As shown in FIGS. 1 and 2, a display device 100 may include a display panel 10 and display driving circuits for driving the display panel 10, as components for displaying images.

The display panel 10 may include a display area AA in which images are displayed and a non-display area NA in which no image is displayed. The non-display area NA may be an outer area of the display area AA and may also be a bezel area. The whole or part of the non-display area NA may be an area visible from the front surface of the display device 100 or an area that is bent and not visible from the front surface of the display device 100.

The display panel 10 may include a plurality of subpixels SP. The display panel 10 may further include various types of signal lines to drive the plurality of subpixels SP. For example, various types of signal lines may include a plurality of data lines DL transferring data signals (also referred to as data voltages or image signals) and a plurality of gate lines GL transferring gate signals (also referred to as scan signals), but embodiments of the disclosure are not limited thereto.

The plurality of data lines DL and the plurality of gate lines GL may cross each other. Each of the plurality of data lines DL may be disposed while extending in a first direction. Each of the plurality of gate lines GL may be disposed while extending in a second direction. The first direction may be a column direction, and the second direction may be a row direction. The first direction may be the row direction, and the second direction may be the column direction.

The display device 100 according to embodiments of the disclosure may be a liquid crystal display device or a self-emission display device in which the display panel 10 emits light by itself. Where the display device 100 according to example embodiments of the disclosure is a self-luminous display device, each of the plurality of subpixels SP may include a light emitting element ED and a pixel driving circuit SPC for driving the light emitting element ED.

The pixel driving circuit SPC may include a driving transistor DRT, a scan transistor SCT, and a storage capacitor Cst.

The driving transistor DRT may control a current flowing to the light emitting element ED to drive the light emitting element ED. The scan transistor SCT may transfer the data voltage Vdata to the second node N2 which is the gate node of the driving transistor DRT. The storage capacitor Cst may be configured to maintain a voltage for a predetermined period of time.

Th light emitting element ED may include a first electrode AE, a second electrode CE, and a light emitting layer 170 positioned between the first electrode AE and the second electrode CE. The first electrode AE may be a pixel electrode involved in the formation of the light emitting element ED of each subpixel SP. The first electrode AE may be electrically connected to the first node N1 of the driving transistor DRT. The second electrode CE may be a common electrode involved in the formation of the light emitting elements ED of all of the subpixels SP. A base voltage EVSS may be applied to the second electrode CE.

For example, the light emitting element ED may be an organic light emitting diode OLED, an inorganic light emitting diode (LED), or a quantum dot light emitting element, which is a self-luminous semiconductor crystal, but embodiments of the disclosure are not limited thereto.

The driving transistor DRT is a transistor for driving the light emitting element ED, and may include a first node N1, a second node N2, and a third node N3. The first node N1 may be a source node or a drain node, and may be electrically connected to the first electrode AE of the light emitting element ED. The second node N2 is a gate node and may be electrically connected to the source node or drain node of the scan transistor SCT. The third node N3 may be a drain node or a source node, and may be electrically connected to a driving voltage line DVL that supplies the driving voltage EVDD. For convenience of description, in the example described below, the first node N1 may be a source node and the third node N3 may be a drain node, but embodiments of the disclosure are not limited thereto.

The scan transistor SCT may switch the connection between the data line DL and the second node N2 of the driving transistor DRT. In response to the scan signal SCAN supplied from the scan line SCL which is a kind of the gate line GL, the scan transistor SCT may control connection between the second node N2 of the driving transistor DRT and a corresponding data line DL among the plurality of data lines DL.

The storage capacitor Cst may be configured between the first node N1 and second node N2 of the driving transistor DRT.

The structure of the subpixel SP illustrated in FIG. 2 is an example for description, and may further include one or more transistors, or one or more storage capacitors, but embodiments of the disclosure are not limited thereto. The plurality of subpixels SP may have the same structure, or some of the plurality of subpixels SP may have a different structure. Each of the driving transistor DRT and the scan transistor SCT may be an n-type transistor or a p-type transistor. One of the driving transistor DRT and the scan transistor SCT may include one of an oxide semiconductor layer, a polysilicon semiconductor layer, and a low-temperature polysilicon semiconductor layer, but embodiments of the disclosure are not limited thereto.

The display driving circuits may include a data driving circuit 20, a gate driving circuit 30, and a display controller 40.

The data driving circuit 20 may be a circuit for driving a plurality of data lines DL. The data driving circuit 20 may output data signals to the plurality of data lines DL. The gate driving circuit 30 may be a circuit for driving a plurality of gate lines GL. The gate driving circuit 30 may supply gate signals to the plurality of gate lines GL.

The display controller 40 may be a device for controlling the data driving circuit 20 and the gate driving circuit 30. The display controller 40 may control driving timings for the plurality of data lines DL and driving timings for the plurality of gate lines GL.

The display controller 40 may supply a data driving control signal to the data driving circuit 20 to control the data driving circuit 20 and may supply a gate driving control signal to the gate driving circuit 30 to control the gate driving circuit 30.

The data driving circuit 20 may supply data signals to the plurality of data lines DL according to the driving timing control of the display controller 40. The data driving circuit 20 may receive digital image data from the display controller 40 and may convert the received image data into analog data signals and output them to the plurality of data lines DL.

The gate driving circuit 30 may supply gate signals to the plurality of gate lines GL according to the timing control of the display controller 40. The gate driving circuit 30 may receive a first gate voltage corresponding to a turn-on level voltage and a second gate voltage corresponding to a turn-off level voltage, along with various gate driving control signals (e.g., start signal and reset signal), generate gate signals, and supply the generated gate signals to the plurality of gate lines GL.

The gate driving circuit 30 may be connected with the display panel 10 by TAB method or connected to a bonding pad of the display panel 10 by a COG or COP method or may be connected with the display panel 10 according to a COF method. Alternatively, the gate driving circuit 30 may be formed in a gate in panel (GIP) type, in the non-display area NA of the display panel 10.

The gate driving circuit 30 may be disposed on or connected to the substrate, but embodiments of the disclosure are not limited thereto. For example, the gate driving circuit 30 that is of a GIP type may be disposed in the non-display area NA of the substrate. The gate driving circuit 30 that is of a chip-on-glass (COG) type or chip-on-film (COF) type may be connected to the substrate.

At least one of the data driving circuit 20 and the gate driving circuit 30 may be disposed in the display area AA of the display panel 10. For example, at least one of the data driving circuit 20 and the gate driving circuit 30 may be disposed not to overlap the subpixels SP or to overlap all or some of the subpixels SP, but embodiments of the disclosure are not limited thereto.

The data driving circuit 20 may be connected to one side (e.g., an upper or lower side) of the display panel 10. Depending on the driving scheme or the panel design scheme, data driving circuits 20 may be connected with both the sides (e.g., both the upper and lower sides) of the display panel 10, or two or more of the four sides of the display panel 10, but embodiments of the disclosure are not limited thereto.

The gate driving circuit 30 may be connected to one side (e.g., a left or right side) of the display panel 10. Depending on the driving scheme or the panel design scheme, gate driving circuits 30 may be connected with both the sides (e.g., both the left and right sides) of the display panel 10, or two or more of the four sides of the display panel 10, but embodiments of the disclosure are not limited thereto.

The display controller 40 may be implemented as a separate component from the data driving circuit 20, or the display controller 140 and the data driving circuit 20 may be integrated into an integrated circuit (IC), but embodiments of the disclosure are not limited thereto.

The display controller 40 may be a timing display controller used in typical display technology, a control device that may perform other control functions as well as the functions of the timing display controller, or a control device other than the timing controller, or may be a circuit in the control device. The display controller 40 may be implemented as various circuits or electronic components, such as an integrated circuit (IC), a field programmable gate array (FPGA), an application specific integrated circuit (ASIC), or a processor, but embodiments of the disclosure are not limited thereto.

The display controller 40 may be mounted on a printed circuit board or a flexible printed circuit and may be electrically connected with the data driving circuit 20 and the gate driving circuit 30 through the printed circuit board or the flexible printed circuit.

The display controller 40 may transmit/receive signals to/from the data driving circuit 20 according to one or more predetermined interfaces. The interface may include, e.g., a low voltage differential signaling (LVDS) interface, an EPI interface, and a serial peripheral interface (SP), but embodiments of the disclosure are not limited thereto.

To provide a touch sensing function as well as an image display function, the display device 100 according to embodiments of the disclosure may include a touch panel TP and a touch sensing circuit 50 that senses the touch panel TP to detect whether a touch occurs by a touch object, such as a finger or pen, or the position of the touch. The touch panel TP may be a touch portion, but embodiments of the disclosure are not limited thereto.

The touch panel TP may include a plurality of touch electrodes TE as touch sensors. The touch panel TP may exist outside or inside the display panel 10. When the touch panel TP exists outside the display panel 10, the touch panel TP is referred to as an external type. When the touch panel TP is of the external type, the touch panel TP and the display panel 10 may be separately manufactured or may be combined during an assembly process. When the touch panel TP exists inside the display panel 10, the touch panel TP is referred to as an internal type. When the touch panel TP is of the internal type, the touch panel TP may be formed in the display panel 10 during a manufacturing process of the display panel 10. For example, the touch panel TP may be disposed on the encapsulation layer ENCAP in the display panel 10.

The touch sensing circuit 50 may include a touch driving circuit 60 that drives and senses the touch panel TP and generates and outputs touch sensing data and a touch controller 70 that may detect an occurrence of a touch or the position of the touch using touch sensing data.

The touch driving circuit 60 may supply a touch driving signal to at least one of the plurality of touch electrodes TE and may sense at least one of the plurality of touch electrodes TE to generate touch sensing data.

The touch sensing circuit 50 may perform touch sensing in a self-capacitance sensing scheme or a mutual-capacitance sensing scheme.

When the touch sensing circuit 50 performs touch sensing in the self-capacitance sensing scheme, the touch sensing circuit 50 may perform touch sensing based on capacitance between each touch electrode and the touch object (e.g., finger or pen).

According to the self-capacitance sensing scheme, each of the plurality of touch electrodes may serve both as a driving touch electrode and as a sensing touch electrode. The touch driving circuit 60 may drive all or some of the plurality of touch electrodes and sense all or some of the plurality of touch electrodes.

When the touch sensing circuit 50 performs touch sensing in the mutual-capacitance sensing scheme, the touch sensing circuit 50 may perform touch sensing based on capacitance between the touch electrodes.

According to the mutual-capacitance sensing scheme, the plurality of touch electrodes may include driving touch electrodes and sensing touch electrodes. The touch driving circuit 60 may drive the driving touch electrodes and sense the sensing touch electrodes.

The touch driving circuit 60 and the touch controller 70 included in the touch sensing circuit 50 may be implemented as separate devices or as a single device. The touch driving circuit 60 and the data driving circuit 20 may be implemented as separate devices or as a single device.

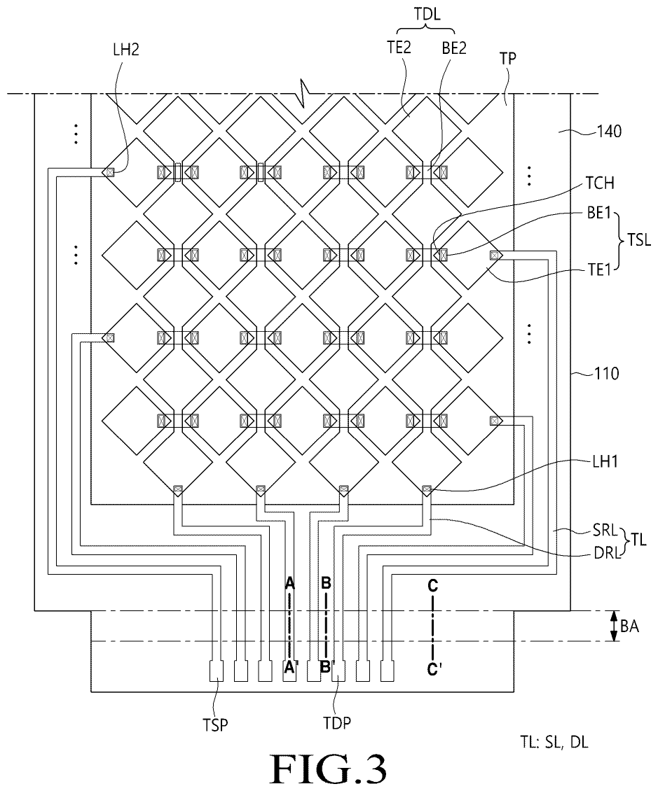

FIG. 3 is a plan view illustrating a display panel according to example embodiments of the disclosure.

As shown in FIG. 3, the display panel 10 may include a non-display area NA disposed outside the display area AA, and the non-display area NA may include a bending area BA disposed on one side of the display area AA. The bending area BA may be an area where the base substrate 110 may be bent.

The touch panel TP may include a first touch electrode TEL and a second touch electrode TE2. The presence or absence of a touch and a touch position may be sensed in the display area AA through the first touch electrode TE1 and the second touch electrode TE2.

The touch panel TP may further include a plurality of touch routing lines TL for electrically connecting the plurality of touch electrodes TE, the touch driving pad TDP, and the touch sensing pad TSP. The touch routing line TL in the present embodiment may include a sensing routing line SRL, a driving routing line DRL, a touch sensing line TSL and a touch driving line TDL. For example, the touch sensing line TSL and the touch driving line TDL may be disposed to cross each other on the touch buffer layer 140.

The touch sensing line TSL may include a plurality of first touch electrodes TEL and first bridge electrodes BE1 electrically connecting the plurality of first touch electrodes TE1. The plurality of first touch electrodes TE1 may be spaced apart from each other at regular intervals along one direction on the touch buffer layer 140. Each of the plurality of first touch electrodes TE1 may be electrically connected to an adjacent first touch electrode TE1 through a first bridge electrode BE1.

The first bridge electrode BE1 may be formed on the touch buffer layer 140. For example, the first bridge electrode BE1 may be exposed through a touch contact hole TCH penetrating the insulation layer positioned between the first touch electrode TEL and the first bridge electrode BE1 to be electrically connected to the first touch electrode TE1.

The touch driving line TDL may include a plurality of second touch electrodes TE2 and second bridge electrodes BE2 electrically connecting the plurality of second touch electrodes TE2. The plurality of second touch electrodes TE2 may be spaced apart from each other at regular intervals along a direction crossing the touch sensing line TSL. For example, each of the plurality of second touch electrodes TE2 may be electrically connected to the adjacent second touch electrode TE2 through the second bridge electrode BE2.

The second bridge electrode BE2 may be disposed on the same plane as the second touch electrode TE2 to be electrically connected to the second touch electrode TE2 without a separate contact hole.

The touch driving line TDL may be electrically connected to the touch driving circuit 60 through the driving routing line DRL and the touch driving pad TDP. Further, the touch sensing line TSL may be electrically connected to the touch driving circuit 60 through the sensing routing line SRL and the touch sensing pad TSP.

The driving routing line DRL may be electrically connected to the second touch electrode TE2 through the first routing contact hole LH1 or may be directly connected to the second touch electrode TE2. The driving routing line DRL may transmit a touch driving pulse supplied through the touch driving pad TDP to the touch driving line TDL. The sensing routing line SRL may be electrically connected to the first touch electrode TE1 through the second routing contact hole LH2 or may be directly connected to the first touch electrode TE1. The sensing routing line SRL may transmit a touch signal detected from the touch sensing line TSL to the touch sensing pad TSP.

The first touch electrode TEL and the second touch electrode TE2, and the driving routing line DRL and the sensing routing line SRL may be formed as a single layer or multiple layers constituted of any one, or an alloy, of molybdenum (Mo), aluminum (Al), chromium (Cr), gold (Au), titanium (Ti), nickel (Ni), neodymium (Nd), and copper (Cu).

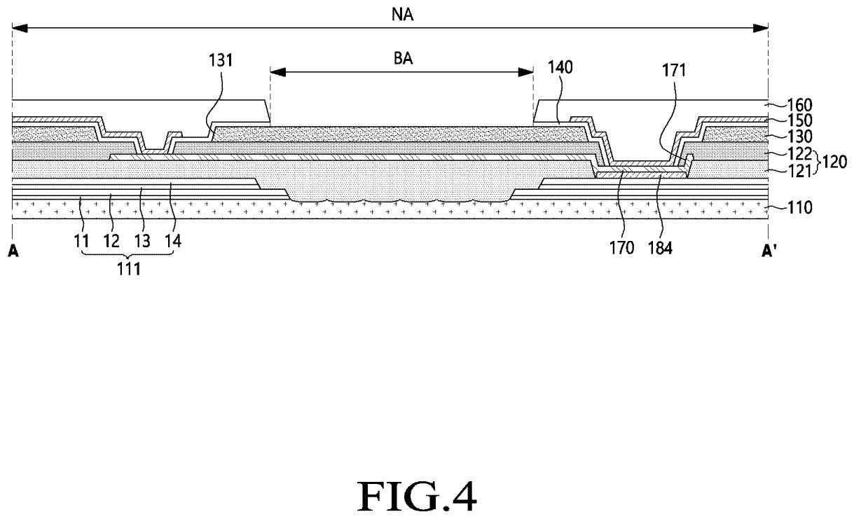

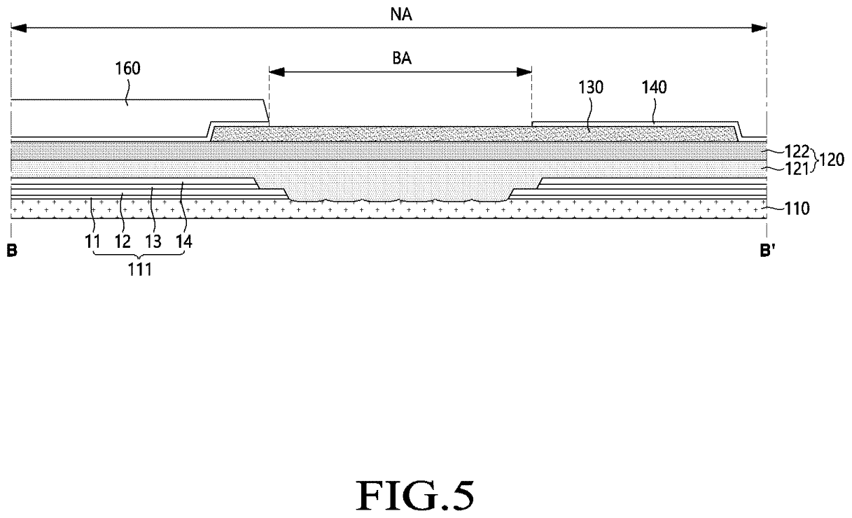

FIG. 4 is a cross-sectional view taken along line A-A′ in FIG. 3, and FIG. 5 is a cross-sectional view taken along line B-B′ in FIG. 3.

FIG. 4 is a view illustrating a portion where the touch routing line TL is disposed in the non-display area NA, and FIG. 5 is a view illustrating a portion where the touch routing line TL is not disposed in the non-display area NA.

As shown in FIGS. 4 and 5, the non-display area NA of the display device 100 may include a base substrate 110, a planarization layer 120, a bank 130, a touch buffer layer 140, a touch sensor portion 150, and a protective layer 160.

The base substrate 110 is for supporting various components of the display device 100 and may be formed of an insulating material, such as a glass substrate or a plastic substrate. Although the base substrate 110 is illustrated as one layer in the present embodiment, the base substrate 110 may be formed of a plurality of layers.

The base substrate 110 may have a concave curved pattern formed on one surface facing the planarization layer 120. For example, the concave curved pattern may be formed in an area overlapping the bending area BA, and concave hemispherical patterns may be disposed adjacent to each other.

As described above, when the concave curved pattern is formed on the base substrate 110, the position of the neutral plane formed in the bending area BA may be easily adjusted. As such, when a neutral plane is disposed in the bending area BA where the metal layer and the inorganic material layer are not disposed, cracks may be prevented or suppressed from occurring in the display panel 10 during bending.

A plurality of buffer layers 111 for blocking moisture and oxygen introduced therein may be disposed on the base substrate 110. For example, the buffer layer 111 may include a first buffer layer 11, a second buffer layer 12, a third buffer layer 13, and a fourth buffer layer 14. The buffer layer 111 may be formed of an inorganic material such as silicon nitride (SiNx), silicon oxide (SiOx), silicon oxynitride (SiON), and aluminum oxide (Al₂O₃), but embodiments of the disclosure are not limited thereto.

The buffer layer 111 may not overlap the bending area BA. In other words, the buffer layer 111 may not be disposed in the bending area BA. In an embodiment, the buffer layer 111 in the bending area BA may be removed to form the concave curved pattern. This is because, including the inorganic material buffer layer 111 in the bending area BA makes it challenging to bend the display device 100, and there is a risk of cracks forming in the buffer layer 111.

The planarization layer 120 is for planarizing the upper portion of the base substrate 110, and may be disposed on the buffer layer 111 and the base substrate 110. For example, the planarization layer 120 may be formed of an organic material such as acrylic resin, epoxy resin, phenolic resin, polyamide resin, and polyimide resin. In an embodiment, the planarization layer 120 may fill the concave curved pattern formed in the buffer layers 111.

The planarization layer 120 may include a plurality of layers. For example, the planarization layer 120 may include a first planarization layer 121 and a second planarization layer 122 disposed on the first planarization layer 121. A connection line 170 may be disposed between the first planarization layer 121 and the second planarization layer 122, and a detailed description thereof is described below.

The bank 130 is for partitioning the pixels and may be disposed on the planarization layer 120. The bank 130 may include a plurality of openings 131 in the non-display area NA. For example, the opening 131 may be disposed not to overlap the bending area BA in the non-display area NA. Specifically, the openings 131 may be disposed on two opposite sides with the bending area BA interposed therebetween.

The touch buffer layer 140 may be disposed on a portion of the planarization layer 120 and the bank 130. For example, the touch buffer layer 140 may be disposed not to overlap the bending area BA and may be formed of an inorganic material, such as silicon nitride (SiNx), silicon oxide (SiOx), silicon oxynitride (SiON), or aluminum oxide (Al₂O₃).

The touch sensor portion 150 may be disposed on the touch buffer layer 140. For example, the touch sensor portion 150 may include a touch electrode TE disposed on the touch buffer layer 140, and a touch routing line TL disposed on the touch buffer layer 140 and electrically connected to the touch electrode TE.

The width of the touch sensor portion 150 may be formed to be smaller than the width of the touch buffer layer 140 to expose a portion of the outer edge of the touch buffer layer 140. This is because when the width of the touch sensor portion 150 is formed to be larger than the width of the touch buffer layer 140, the end portion of the touch sensor portion 150 protrudes to the bending area BA, causing cracks or moisture to penetrate into the inside when bending is implemented.

Meanwhile, since the touch buffer layer 140 is disposed not to overlap the bending area BA, the touch sensor portion 150 may also not overlap the bending area BA. In other words, the touch sensor portion 150 may not be disposed in the bending area BA. As described above, as the touch sensor portion 150 is disconnected in the bending area BA, a connection line 170 for electrically connecting the disconnected portion may be needed. For example, the connection line 170 may be disposed in the non-display area NA and may be interposed between the first planarization layer 121 and the second planarization layer 122. In this case, to bring the touch sensor portion 150 and the connection line 170 into contact with each other, the planarization layer 120 and the touch buffer layer 140 may include a contact hole in a portion that does not overlap the bending area BA.

A portion of the connection line 170 disposed outside the bending area BA, i.e., in an area adjacent to the touch driving pad TDP, is recessed toward the first planarization layer 121 to form a step 171, and the second planarization layer 122 may cover a portion of the step 171. Further, the touch sensor portion 150 may extend from the bank 130 to the step 171, and its lower surface may contact the connection line 170. In other words, a portion of the second planarization layer 122 may protrude in a direction in which the first planarization layer 121 is disposed to be disposed between the outer surface of the touch sensor portion 150 and the step 171 of the connection line 170.

As such, as a portion of the connection line 170 is recessed toward the first planarization layer 121 to form the step 171, the area of the touch sensor portion 150 disposed in the step 171 may be increased to enhance touch sensitivity. Further, as the second planarization layer 122 is disposed between the outer surface of the touch sensor portion 150 and the step 171 of the connection line 170, moisture that may be introduced into the connection line 170 may be blocked to enhance moisture resistance.

The touch buffer layer 140 may not overlap the bending area BA. In other words, the touch buffer layer 140 may not be disposed in the bending area BA. This is because disposing the inorganic touch buffer layer 140 in the bending area BA makes it challenging to bend the display device 100, and there is a risk of cracks forming in the inorganic touch buffer layer 140.

The protective layer 160 may cover the touch sensor portion 150 on the touch buffer layer 140 to protect the underlying touch sensor portion 150 from moisture, oxygen, and impact. As described above, as the protective layer 160 is disposed on the touch buffer layer 140, the protective layer 160 may also not overlap the bending area BA like the touch buffer layer 140.

The protective layer 160 may be formed of an organic material such as an acrylic resin, an epoxy resin, a phenolic resin, a polyamide resin, and a polyimide resin.

An end portion of the protective layer 160 may be disposed not to exceed an end portion of the touch buffer layer 140. For example, if the end portion of the protective layer 160 formed of an organic material exceeds the end portion of the touch buffer layer 140, the protective layer 160 may overlap the bending area BA, thickening the display panel 10 in the bending area BA and hence making it difficult to implement bending. Therefore, in the present embodiment, the end portion of the protective layer 160 does not exceed the end portion of the touch buffer layer 140, thereby facilitating the bending of the display panel 10. For example, the lower end portion of the protective layer 160 may be disposed parallel to the upper end portion of the touch buffer layer 140. The arrangement of the protective layer 160 is not limited to the examples, and the width of the protective layer 160 may be formed to be smaller than the width of the touch buffer layer 140 to expose a portion of the edge of the touch buffer layer 140. In this case, the width of the protective layer 160 may be larger than the width of the touch sensor portion 150 and smaller than the width of the touch buffer layer 140.

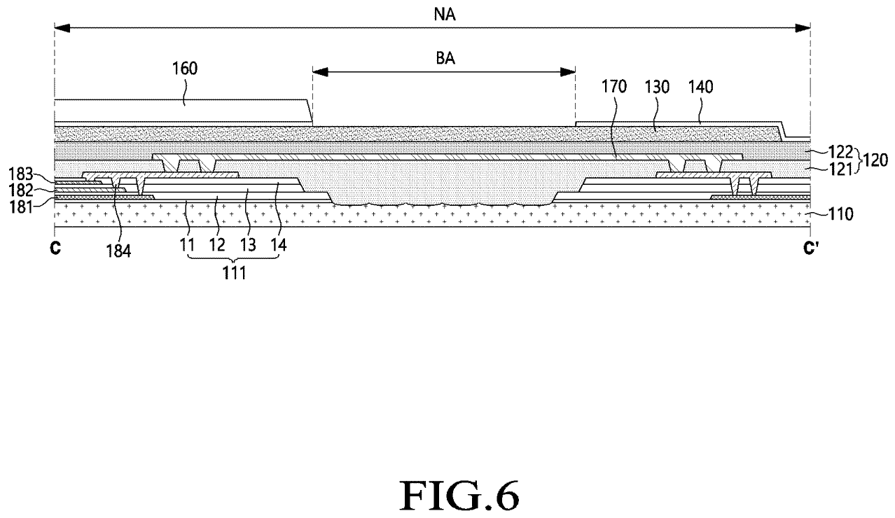

FIG. 6 is a cross-sectional view taken along line C-C′ in FIG. 3.

FIG. 6 illustrates a portion of the non-display area NA where the touch sensor portion 150 is not disposed, and as shown in FIG. 6, the non-display area NA of the display device 100 may include a base substrate 110, a planarization layer 120, a bank 130, a touch buffer layer 140, a touch sensor portion 150, and a protective layer 160.

The base substrate 110 may have a concave curved pattern formed on one surface facing the planarization layer 120. For example, the concave curved pattern may be formed in an area overlapping the bending area BA, and concave hemispherical patterns may be disposed adjacent to each other.

A plurality of buffer layers 111 for blocking moisture and oxygen introduced therein may be disposed on the base substrate 110. For example, the buffer layer 111 may include a first buffer layer 11, a second buffer layer 12, a third buffer layer 13, and a fourth buffer layer 14. The buffer layer 111 may be formed of an inorganic material such as silicon nitride (SiNx), silicon oxide (SiOx), silicon oxynitride (SiON), and aluminum oxide (Al₂O₃), but embodiments of the disclosure are not limited thereto.

The first gate line 181 may be disposed on the first buffer layer 11, and the first gate line 181 may be covered by the second buffer layer 12. A second gate line 182 may be disposed on the second buffer layer 12, and the second gate line 182 may be covered by the third buffer layer 13. A third gate line 183 may be disposed on the third buffer layer 13, and the third gate line 183 may be covered by the fourth buffer layer 14. Here, the first gate line 181 to the third gate line 183 may be electrically connected to the signal lines, respectively.

A source drain line 184 for supplying power may be disposed on the fourth buffer layer 14. In this case, to electrically connect the source drain line 184 to the first gate line 181 to the third gate line 183, a contact hole may be formed in the second buffer layer 12, the third buffer layer 13, and the fourth buffer layer 14.

The planarization layer 120 is for planarizing the upper portion of the base substrate 110, and may be disposed on the base substrate 110, the fourth buffer layer 14, and the first gate line 181. For example, the planarization layer 120 may be formed of an organic material such as acrylic resin, epoxy resin, phenolic resin, polyamide resin, and polyimide resin.

The planarization layer 120 may include a first planarization layer 121 and a second planarization layer 122 disposed on the first planarization layer 121. A connection line 170 may be disposed between the first planarization layer 121 and the second planarization layer 122, and the connection line 170 may be electrically connected to the source drain line 184 through a contact hole formed in the first planarization layer 121.

The bank 130 is for partitioning the pixels and may be disposed on the planarization layer 120.

The touch buffer layer 140 may be disposed on a portion of the bank 130. For example, the touch buffer layer 140 may be disposed not to overlap the bending area BA and may be formed of an inorganic material, such as silicon nitride (SiNx), silicon oxide (SiOx), silicon oxynitride (SiON), or aluminum oxide (Al₂O₃).

The touch sensor portion 150 may be disposed on the touch buffer layer 140. For example, the touch sensor portion 150 may include a touch electrode TE disposed on the touch buffer layer 140, and a touch routing line TL disposed on the touch buffer layer 140 and electrically connected to the touch electrode TE.

The protective layer 160 may cover the touch sensor portion 150 on the touch buffer layer 140 to protect the underlying touch sensor portion 150 from moisture, oxygen, and impact. As described above, as the protective layer 160 is disposed on the touch buffer layer 140, the protective layer 160 may also not overlap the bending area BA like the touch buffer layer 140.

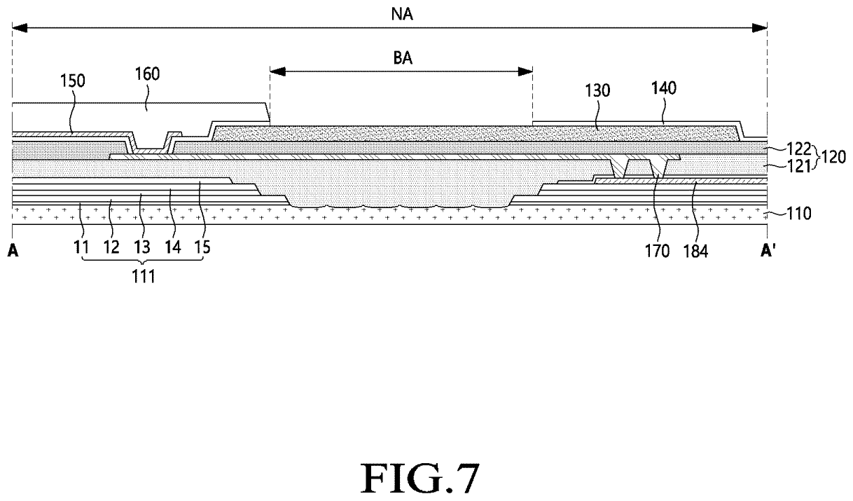

FIGS. 7 to 9 are cross-sectional views illustrating a display device according to another example embodiment.

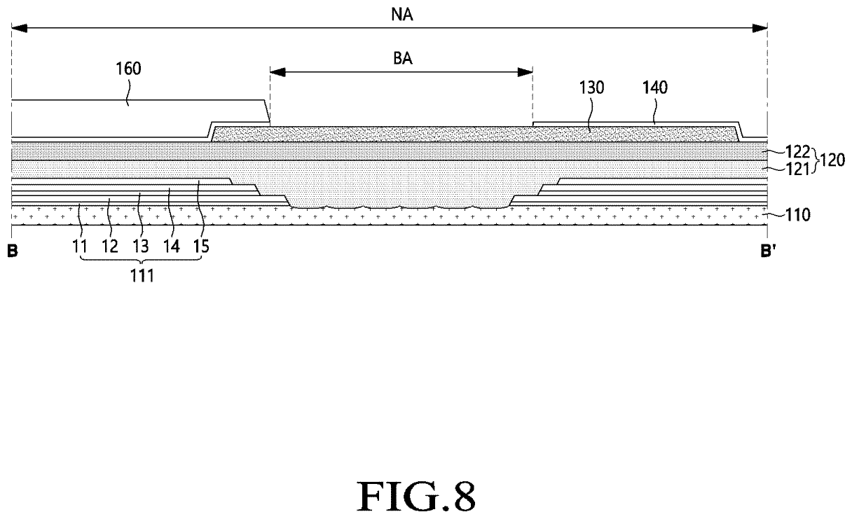

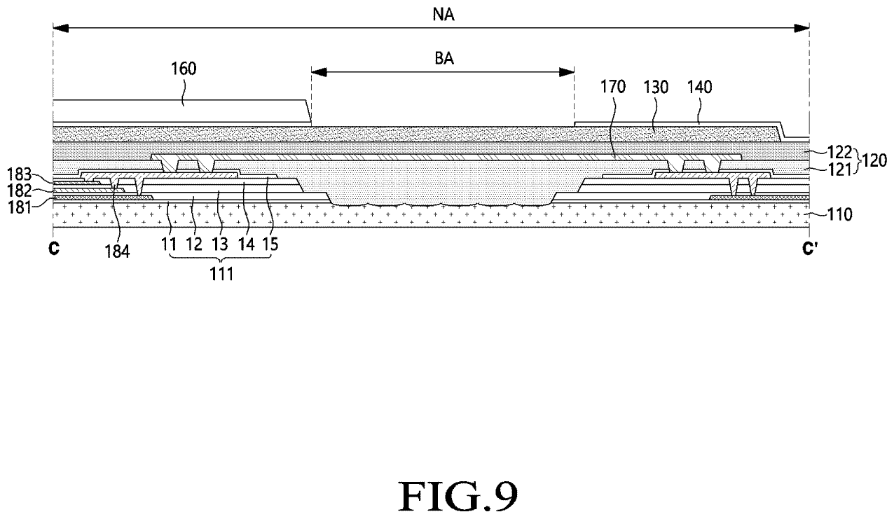

FIG. 7 is a view illustrating a portion where the touch routing line TL is disposed in the non-display area NA, FIG. 8 is a view illustrating a portion where the touch routing line TL is not disposed in the non-display area NA, and FIG. 9 is a view illustrating a portion where the touch sensor portion 150 is not disposed in the non-display area NA. In this example embodiment, the description focuses primarily on differences from the above-described example embodiment.

As shown in FIGS. 7 to 9, the non-display area NA of the display device may include a base substrate 110, a planarization layer 120, a bank 130, a touch buffer layer 140, a touch sensor portion 150, and a protective layer 160.

The base substrate 110 may have a concave curved pattern formed on one surface facing the planarization layer 120. For example, the concave curved pattern may be formed in an area overlapping the bending area BA, and concave hemispherical patterns may be disposed adjacent to each other.

A plurality of buffer layers 111 for blocking moisture and oxygen introduced therein may be disposed on the base substrate 110. For example, the buffer layer 111 may include a first buffer layer 11, a second buffer layer 12, a third buffer layer 13, a fourth buffer layer 14, and a fifth buffer layer 15. The buffer layer 111 may be formed of an inorganic material such as silicon nitride (SiNx), silicon oxide (SiOx), silicon oxynitride (SiON), and aluminum oxide (Al₂O₃), but embodiments of the disclosure are not limited thereto.

The first gate line 181 may be disposed on the first buffer layer 11, and the first gate line 181 may be covered by the second buffer layer 12. A second gate line 182 may be disposed on the second buffer layer 12, and the second gate line 182 may be covered by the third buffer layer 13. A third gate line 183 may be disposed on the third buffer layer 13, and the third gate line 183 may be covered by the fourth buffer layer 14. Here, the first gate line 181 to the third gate line 183 may be electrically connected to the signal lines, respectively.

A source drain line 184 for supplying power may be disposed on the fourth buffer layer 14. In this case, to electrically connect the source drain line 184 to the first gate line 181 to the third gate line 183, a contact hole may be formed in the second buffer layer 12, the third buffer layer 13, and the fourth buffer layer 14. Further, the source drain line 184 may be covered by the fifth buffer layer 15.

The present embodiment may further include the fifth buffer layer 15 covering the source drain line 184 as compared with the embodiments of FIGS. 4 to 6 described above. As described above, by further including the fifth buffer layer 15, moisture that may be introduced into the source drain line 184 may be blocked, enhancing moisture resistance.

The planarization layer 120 is for planarizing the upper portion of the base substrate 110 and may be disposed on the base substrate 110 and the fifth buffer layer 15. For example, the planarization layer 120 may be formed of an organic material such as acrylic resin, epoxy resin, phenolic resin, polyamide resin, and polyimide resin.

The planarization layer 120 may include a first planarization layer 121 and a second planarization layer 122 disposed on the first planarization layer 121. A connection line 170 may be disposed between the first planarization layer 121 and the second planarization layer 122, and the connection line 170 may be electrically connected to the source drain line 184 through a contact hole formed in the first planarization layer 121 and the fifth buffer layer 15.

The bank 130 is for partitioning the pixels and may be disposed on the planarization layer 120.

The touch buffer layer 140 may be disposed on a portion of the bank 130. For example, the touch buffer layer 140 may be disposed not to overlap the bending area BA and may be formed of an inorganic material, such as silicon nitride (SiNx), silicon oxide (SiOx), silicon oxynitride (SiON), or aluminum oxide (Al₂O₃).

The touch sensor portion 150 may be disposed on the touch buffer layer 140. For example, the touch sensor portion 150 may include a touch electrode TE disposed on the touch buffer layer 140, and a touch routing line TL disposed on the touch buffer layer 140 and electrically connected to the touch electrode TE.

The touch sensor portion 150 may contact and electrically connect to the connection line 170 disposed thereunder through a contact hole formed in the second planarization layer 122. The touch sensor portion 150 may not be formed outside the bending area BA, i.e., in an area where the touch driving pad TDP is disposed.

The protective layer 160 may cover the touch sensor portion 150 on the touch buffer layer 140 to protect the underlying touch sensor portion 150 from moisture, oxygen, and impact. As described above, as the protective layer 160 is disposed on the touch buffer layer 140, the protective layer 160 may also not overlap the bending area BA like the touch buffer layer 140.

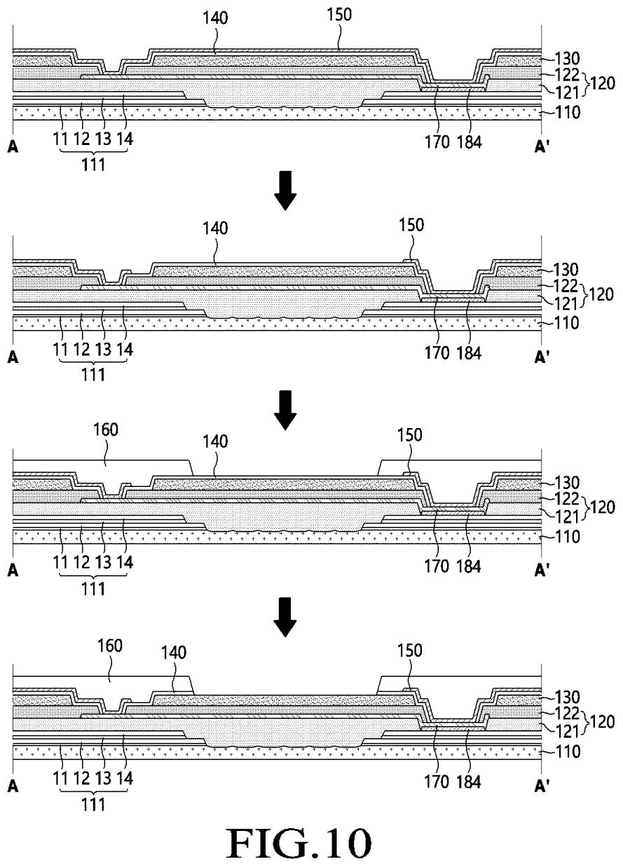

FIG. 10 is a view illustrating a process sequence for manufacturing a display device according to an example embodiment of the disclosure. A process of manufacturing the display device with reference to FIG. 7 is schematically described as follows.

As shown in FIG. 10, a planarization layer 120, a touch buffer layer 140, and a touch sensor portion 150 are sequentially stacked on a base substrate 110. Then, an etching process is performed to pattern the touch sensor portion 150.

After the touch sensor portion 150 is patterned, the protective layer 160 is deposited on the touch sensor portion 150 using a deposition mask. The protective layer 160 formed as described above may be disposed in an area other than the bending area BA in the non-display areas NA.

Thereafter, the touch buffer layer 140 positioned in the bending area BA is removed through dry etching or wet etching. Then, the lower end portion of the protective layer 160 may be disposed parallel to the upper end portion of the touch buffer layer 140.

As described above, since the touch buffer layer 140 positioned in the bending area BA is removed in the last step, tetramethylammonium hydroxide (TMAH) may not remain on the surface of the bank 130 exposed to the bending area BA.

In other words, when the bank 130 is exposed in advance by patterning the touch buffer layer 140 first, tetramethylammonium hydroxide (TMAH), which is a residual component of the developer used in the process of forming the protective layer 160 formed of organic matter, may remain on the bank 130. In this case, when the remaining TMAH reacts with moisture (H₂O), the TMAH may be dissociated to generate a cation of TMA+ (i.e., N(CH₃)₄⁺). Then, when a voltage is applied to the plurality of lines disposed in the bending area BA to evaluate the reliability of the product driving, an electric field between high-voltage and low-voltage lines is generated in a structure in which high-voltage and low-voltage lines are disposed adjacent to each other to reduce the electric field between the same potential level signals when arranging signal lines included in the plurality of lines. In this case, the TMA+ cations remaining on the bending area BA are attracted to the plurality of lines by the generated electric field. For example, when driving at 1 Hz, as the time for a specific line among the plurality of lines to maintain a low voltage increases, TMA+ cations are easily attracted to the low voltage line among the plurality of lines, causing corrosion of the plurality of lines.

To address such a problem, since the display device 100 in the present embodiment removes the touch buffer layer 140 positioned in the bending area BA in the final step, it may be possible to remove the TMAH that may remain on the bank 130.

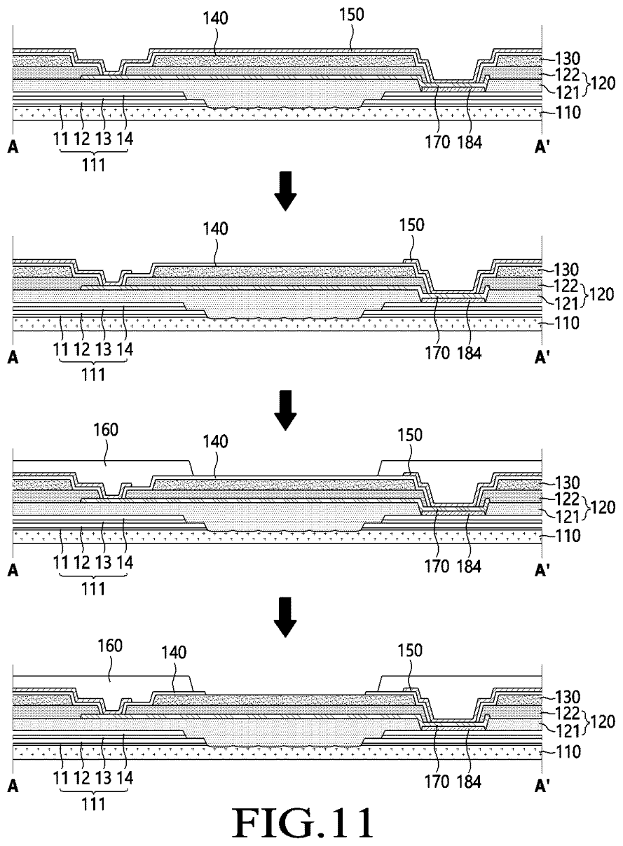

FIG. 11 is a view illustrating a process sequence for manufacturing a display device according to another example embodiment of the disclosure. In this embodiment, the description focuses primarily on differences from the above-described embodiment.

As shown in FIG. 11, a planarization layer 120, a touch buffer layer 140, and a touch sensor portion 150 are sequentially stacked on a base substrate 110. Then, an etching process is performed to pattern the touch sensor portion 150.

After the touch sensor portion 150 is patterned, the protective layer 160 is deposited on the touch sensor portion 150 using a deposition mask. The protective layer 160 formed as described above may be disposed in an area other than the bending area BA in the non-display areas NA.

Thereafter, the touch buffer layer 140 positioned in the bending area BA is removed through dry etching or wet etching. In this case, the width of the protective layer 160 is formed to be smaller than the width of the touch buffer layer 140, so that a portion of the edge of the touch buffer layer 140 adjacent to the bending area BA may be exposed to the outside.

As described above, since the touch buffer layer 140 positioned in the bending area BA is removed in the last step, tetramethylammonium hydroxide (TMAH) may not remain on the surface of the bank 130 exposed to the bending area BA.

Example embodiments of the present disclosure described above are briefly described below.

A display device may comprise a base substrate including a display area and a non-display area, a planarization layer disposed on the base substrate, a bank disposed on the planarization layer, a touch buffer layer disposed on a portion of the bank and the planarization layer, a touch sensor portion disposed on the touch buffer layer, and a protective layer covering the touch sensor portion on the touch buffer layer.

According to some embodiments of the disclosure, the non-display area may include a bending area at one side of the display area. The touch buffer layer may be disposed not to overlap the bending area.

According to some embodiments of the disclosure, the touch sensor portion may be disposed not to overlap the bending area.

According to some embodiments of the disclosure, the touch sensor portion may be electrically connected through a connection line disposed in the non-display area.

According to some embodiments of the disclosure, the planarization layer and the touch buffer layer may include a contact hole in a portion not overlapping the bending area to bring the touch sensor portion and the connection line into contact with each other.

According to some embodiments of the disclosure, the planarization layer may include a first planarization layer and a second planarization layer disposed on the first planarization layer. The connection line may be interposed between the first planarization layer and the second planarization layer.

According to some embodiments of the disclosure, a portion of the connection line may be recessed toward the first planarization layer to form a step. The second planarization layer covers a portion of the step.

According to some embodiments of the disclosure, the touch sensor portion may extend from the bank to the step.

According to some embodiments of the disclosure, the base substrate may have a concave curved pattern on one surface facing the planarization layer.

According to some embodiments of the disclosure, the concave curved pattern may be formed in an area overlapping the bending area.

According to some embodiments of the disclosure, tetramethylammonium hydroxide (TMAH) may not remain in a portion overlapping the bending area on a surface of the bank.

According to some embodiments of the disclosure, the protective layer may be disposed not to overlap the bending area.

According to some embodiments of the disclosure, an end portion of the protective layer may be disposed not to extend beyond an end portion of the touch buffer layer.

According to some embodiments of the disclosure, a lower end portion of the protective layer may be disposed parallel to an upper end portion of the touch buffer layer.

According to some embodiments of the disclosure, a width of the touch sensor portion may be smaller than a width of the touch buffer layer to expose a portion of an outer edge of the touch buffer layer.

According to some embodiments of the disclosure, a width of the protective layer may be smaller than a width of the touch buffer layer to expose a portion of an of the touch buffer layer.

According to some embodiments of the disclosure, a width of the protective layer may be larger than a width of the touch sensor portion and may be smaller than a width of the touch buffer layer.

According to some embodiments of the disclosure, the touch sensor portion may include a touch electrode disposed on the touch buffer layer, and a touch routing line disposed on the touch buffer layer and electrically connected to the touch electrode.

According to some embodiments of the disclosure, the bank may have a plurality of openings formed in the non-display area.

The above-described embodiments are merely examples, and it will be appreciated by one of ordinary skill in the art that various changes may be made thereto without departing from the scope of the disclosure. Accordingly, the example embodiments set forth herein are provided for illustrative purposes, but not to limit the scope of the disclosure, and should be appreciated that the scope of the disclosure is not limited by the example embodiments.

What is claimed is:

1. A display device, comprising:
a base substrate including a display area and a non-display area;
a planarization layer disposed on the base substrate;
a bank disposed on the planarization layer;
a touch buffer layer disposed on a portion of the bank and the planarization layer;
a touch sensor portion disposed on the touch buffer layer; and
a protective layer covering the touch sensor portion on the touch buffer layer.

2. The display device of claim 1, wherein the non-display area includes a bending area at one side of the display area, and
wherein the touch buffer layer is disposed not to overlap the bending area.

3. The display device of claim 2, wherein the touch sensor portion is disposed not to overlap the bending area.

4. The display device of claim 3, wherein the touch sensor portion is electrically connected through a connection line disposed in the non-display area.

5. The display device of claim 4, wherein the planarization layer and the touch buffer layer include a contact hole in a portion not overlapping the bending area to bring the touch sensor portion and the connection line into contact with each other.

6. The display device of claim 4, wherein the planarization layer includes a first planarization layer and a second planarization layer disposed on the first planarization layer, and
wherein the connection line is interposed between the first planarization layer and the second planarization layer.

7. The display device of claim 6, wherein a portion of the connection line is recessed toward the first planarization layer to form a step, and
wherein the second planarization layer covers a portion of the step.

8. The display device of claim 7, wherein the touch sensor portion extends from the bank to the step.

9. The display device of claim 2, wherein the base substrate has a concave curved pattern on one surface facing the planarization layer.

10. The display device of claim 9, wherein the concave curved pattern is formed in an area overlapping the bending area.

11. The display device of claim 2, wherein tetramethylammonium hydroxide (TMAH) does not remain in a portion overlapping the bending area on a surface of the bank.

12. The display device of claim 2, wherein the protective layer is disposed not to overlap the bending area.

13. The display device of claim 1, wherein an end portion of the protective layer is disposed not to extend beyond an end portion of the touch buffer layer.

14. The display device of claim 1, wherein a lower end portion of the protective layer is disposed parallel to an upper end portion of the touch buffer layer.

15. The display device of claim 1, wherein a width of the touch sensor portion is smaller than a width of the touch buffer layer to expose a portion of an outer edge of the touch buffer layer.

16. The display device of claim 1, wherein a width of the protective layer is smaller than a width of the touch buffer layer to expose a portion of an of the touch buffer layer.

17. The display device of claim 1, wherein a width of the protective layer is larger than a width of the touch sensor portion and is smaller than a width of the touch buffer layer.

18. The display device of claim 1, wherein the touch sensor portion includes:
a touch electrode disposed on the touch buffer layer; and
a touch routing line disposed on the touch buffer layer and electrically connected to the touch electrode.

19. The display device of claim 1, wherein the bank has a plurality of openings formed in the non-display area.

20. A display device, comprising:
a base substrate including a display area and a non-display area;
a plurality of buffer layers disposed on base substrate; and
a planarization layer disposed on the plurality of buffer layers; and
a bank disposed on the planarization layer,
wherein the non-display area includes a bending area where the base substrate is bendable, and
wherein the plurality of buffer layers in the bending area are removed to form a concave curved pattern.
